(19) United States
(12) Patent Application Publication
(10) Pub. No.: US 2021/0259135 A1
(43) Pub. Date: Aug. 19, 2021

(54) HEAT SPREADER FOR A MEMORY MODULE

(71) Applicant: SK hynix Inc., Icheon (KR)

(72) Inventor: Myoung Seo KIM, Icheon (KR)

(21) Appl. No.: 16/924,991

(22) Filed: Jul. 9, 2020

(30) Foreign Application Priority Data
Feb. 14, 2020 (KR) 10-2020-0018512

(51) Int. Cl. H05K 7/20; H01L 23/367; G11C 5/04; H01L 23/40

(52) U.S. Cl. CPC H05K 7/20409; H01L 23/3672; H01L 23/4093; H05K 7/2049; G11C 5/04

(57) ABSTRACT

A heat spreader of a memory module including a printed circuit board (PCB) and a plurality of semiconductor chips on at least one surface of the PCB may include a first heat spreading plate and a second heat spreading plate. The first heat spreading plate may be installed at a front surface of the memory module. The second heat spreading plate may be installed at a rear surface of the memory module. At least one of the first and second heat spreading plates may include a body, a plurality of cooling plates and at least one slot. The body may have a plate shape extended in a lengthwise direction of the memory module. The cooling plates may extend from the body in a widthwise direction of the memory module to shield surfaces of the semiconductor chips. The slot may be formed between the cooling plates.

### CROSS-REFERENCES TO RELATED APPLICATION

The present application claims priority under 35 U.S.C. § 119(a) to Korean application number 10-2020-0018512, filed on Feb. 14, 2020, in the Korean Intellectual Property Office, which is incorporated herein by reference in its entirety.

### BACKGROUND

### 1. Technical Field

Various embodiments may generally relate to an electronic device, and more particularly, to a heat spreader for a memory module.

### 2. Related Art

In order to increase a storage capacity and a processing speed of a memory device applied to a computing system such as a personal computer, a massive workstation, a server, etc., a memory module may be used. The memory module may include a printed circuit board (PCB) and a plurality of memory chips mounted on the PCB.

Memory modules may be classified as a single in-line memory module (SIMM) and a double in-line memory module (DIMM). A SIMM may include memory chips on one surface of the PCB, and a DIMM may include memory chips on both surfaces of the PCB.

As the density of structures in memory chips increases and the number of memory modules present increases, the amount of heat generated by memory modules increases. Excessive heat may decrease the life span of a memory module.

While conventional computing systems have concentrated computing operations in a central processing unit (CPU), recent trends towards remote computing offload those operations to remote processors. Data exchange between a local device and a remote processor may be a memory intensive process, and improving the amount and speed of memory in a system may improve the speed of operations in systems that employ remote computing.

However, improved the performance and speed of computing devices may result in increasing energy consumption and heat generation.

### SUMMARY

In example embodiments of the present disclosure, a heat spreader of a memory module including a printed circuit board (PCB) and a plurality of semiconductor chips on at least one surface of the PCB may include a first heat spreading plate and a second heat spreading plate. The first heat spreading plate may be installed at a front surface of the memory module. The second heat spreading plate may be installed at a rear surface of the memory module. At least one of the first and second heat spreading plates may include a body, a plurality of cooling plates and at least one slot. The body may have a plate shape extended in a lengthwise direction of the memory module. The cooling plates may extend from the body in a widthwise direction of the memory module to cover surfaces of the semiconductor chips. The slot may be formed between the cooling plates.

In example embodiments of the present disclosure, a heat spreader of a memory module including a printed circuit board (PCB) and a plurality of semiconductor chips on at least one surface of the PCB may include a plurality of cooling plates and at least one slot. The cooling plates may be configured to cover surfaces of the semiconductor chips. The slot may be formed between the cooling plates.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a view illustrating a memory module in accordance with example embodiments;

FIG. 2 is a view illustrating a memory module in accordance with example embodiments;

FIG. 3 is a perspective view illustrating a heat spreader in accordance with example embodiments;

FIG. 4 is a perspective view illustrating a memory module with a heat spreader in accordance with example embodiments;

FIGS. 5A and 5B are views illustrating a heat spreader in accordance with example embodiments; and

FIGS. 6A and 6B are views illustrating a heat spreader in accordance with example embodiments.

### DETAILED DESCRIPTION

Various embodiments of the present disclosure will be described in detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present disclosure provides cross-section and/or plan illustrations of specific embodiments. However, those embodiments should not be construed as limiting the inventive concepts in the present disclosure. Although a few embodiments will be shown and described, it will be appreciated by those of ordinary skill in the art that changes may be made to these embodiments without departing from the principles and spirit expressed in the present disclosure.

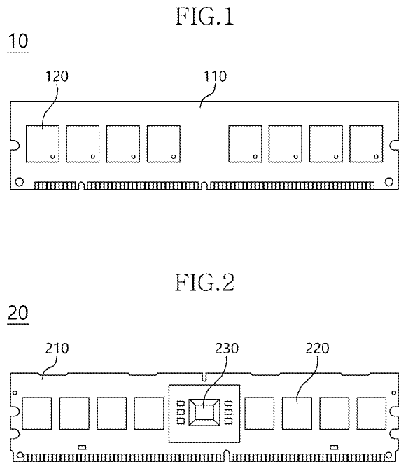

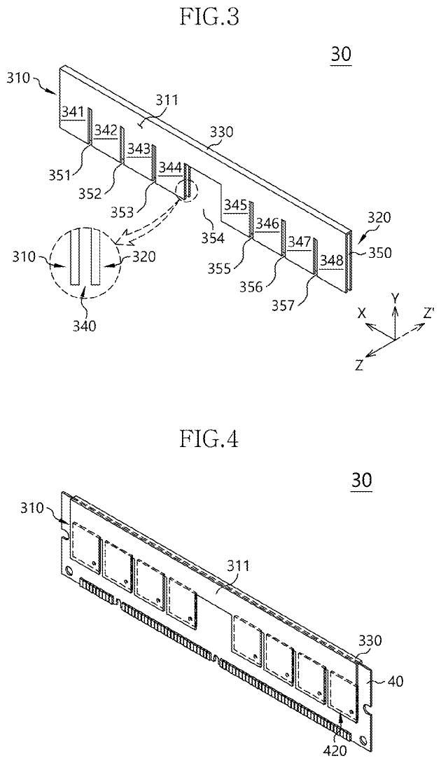

FIGS. 1 and 2 are views illustrating a memory module in accordance with example embodiments.

Referring to FIG. 1, a memory module 10 may be includes a plurality of memory chips 120 mounted on at least one surface of a printed circuit board (PCB) 110.

Referring to FIG. 2, a memory module 20 may be includes a plurality of memory chips 220 and a memory controller 230 mounted on at least one surface of a PCB 220.

The memory chips 220 and the memory controller 230 may be referred to as semiconductor chips.

Structures of the memory modules 10 and 20 are not restricted to the specific structures shown in FIGS. 1 and 2. For example, in other embodiments, the numbers of memory chips 120 and 220 and positions of the memory controller 230 on the PCBs 110 and 210 may be different from the embodiments illustrated in FIG. 1 and FIG. 2.

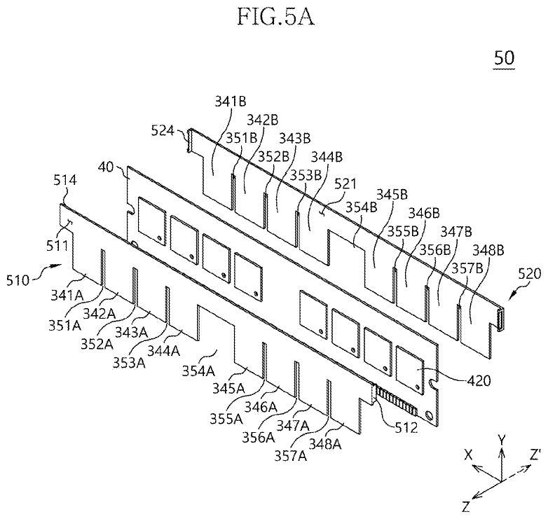

FIG. 3 is a perspective view illustrating a heat spreader in accordance with example embodiments.

Referring to FIG. 3, a heat spreader 30 may include a body 311, a first heat spreading plate 310, a second heat spreading plate 320 and a connecting part 330.

The connecting part 330 may extend for a predetermined length in a lengthwise direction X of the memory modules 10 and 20 along a spine of the heat spreader 30.

The body 311 may have a plate shape. A plane of the body 311 may be parallel to the X-Y plane shown in FIG. 3. The body may be positioned perpendicular to the connecting part 330 that lies along the X-Z plane and extends in the Z-Z′ direction.

First ends of the first heat spreading plate 310 and the second heat spreading plate 320 in the widthwise direction Y may be combined with the connecting part 330 through the body 311. Second ends of the first heat spreading plate 310 and the second heat spreading plate 320 in the widthwise direction Y opposite to the lengthwise direction X may be opened to form a module insertion groove 340. Further, both ends of the first heat spreading plate 310 and the second spreading plate 320 in the lengthwise direction X may provide opened portions 350.

The heat spreader 30 may have a length and a width configured to cover the memory modules 10 and 20. FIG. 3 shows a front surface of a heat spreader 30. The first heat spreader 310 may extend from the front body 311 in the widthwise direction of the heat spreader 30.

At least one of the first and second heat spreading plates 310 and 320 may include a plurality of cooling plates 341, 342, 343, 344, 345, 346, 347 and 348 and at least one slot 351, 352, 353, 354, 355, 356 and 357. The slots may be gaps or spaces between adjacent cooling plates, and the cooling plates 341, 342, 343, 344, 345, 346, 347 and 348 may cover the semiconductor chips 120, 220 and 230 on the memory modules 10 and 20. The slots 351, 352, 353, 354, 355, 356 and 357 may be formed between the cooling plates 341, 342, 343, 344, 345, 346, 347 and 348.

The memory modules 10 and 20 may be combined with the heat spreader 30 through the module insertion groove 340. The surfaces of the semiconductor chips 120, 220 and 230 on the memory modules 10 and 20 may be covered by the cooling plates 341˜348. The cooling plates may transfer heat from the chips into the heat spreaders 30 and protect the chips from damage.

Heat generated by the semiconductor chips 120, 220 and 230 in the memory modules 10 and 20 may be absorbed and transferred to the cooling plates 341˜348 and the body 311. The heat transferred to the cooling plates 341˜348, the body 311 from the semiconductor chips 120, 220 may be dissipated by air that flows through the slots 351˜357.

A computing system may include a fan configured to circulate air to decrease temperatures of electronic devices in the computing system. Cooling air generated by the fan may move through the slots 351˜357 to effectively cool and dissipate heat generated by the memory modules 10 and 20 and the heat in the cooling plates 341˜348 and the body 311.

The slots 351˜357 may be disposed between adjacent semiconductor chips, and ends of the heat spreaders 30 so that side surfaces of the semiconductor chips are exposed to airflow within an enclosure, thereby removing heat directly from the side surfaces. Conventional heat spreaders have contiguous bodies that cover gaps between adjacent chips. As a result, hot air can be trapped in air pockets between chips. Accordingly, embodiments of the present disclosure improve cooling by exposing sides of the chips to circulating airflow and reducing the extent to which hot air can be trapped by the heat spreader.

In example embodiments, the heat spreader 30 may include a metal having a high thermal conductivity such as aluminum, copper, an alloy thereof, etc. Embodiments are not restricted to a specific material.

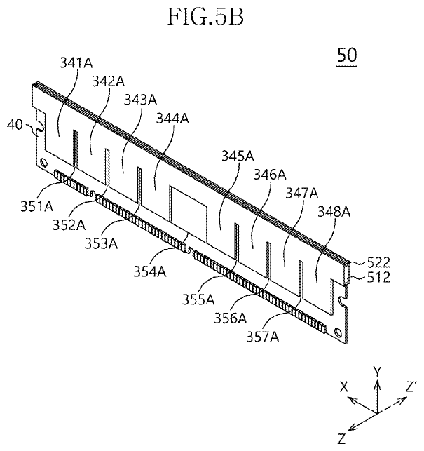

FIG. 4 is a perspective view illustrating a memory module with a heat spreader in accordance with example embodiments.

Referring to FIG. 4, a memory module 40 may be inserted into the module insertion groove 340 of the heat spreader 30.

In example embodiments, the first heat spreading plate 310 may be positioned on a front surface of the memory module 40. The second heat spreading plate 320 may be positioned on a rear surface of the memory module 40.

The cooling plates 341˜348 disposed in at least one of the first and second heat spreading plates 310 and 320 may cover exposed surfaces of the semiconductor chips 420 on the memory module 40 to absorb heat generated from the semiconductor chips 420.

The slots 351˜357 formed between the cooling plates 341˜348 may dissipate the heat in the cooling plates 341˜348 and the body 311. Further, the slots 351˜357 may also dissipate the heat generated from the semiconductor chips 420.

Therefore, the heat in the semiconductor chips 420 may be effectively dissipated to control the heat of the memory module 40 and to minimize power consumption of the memory module 40.

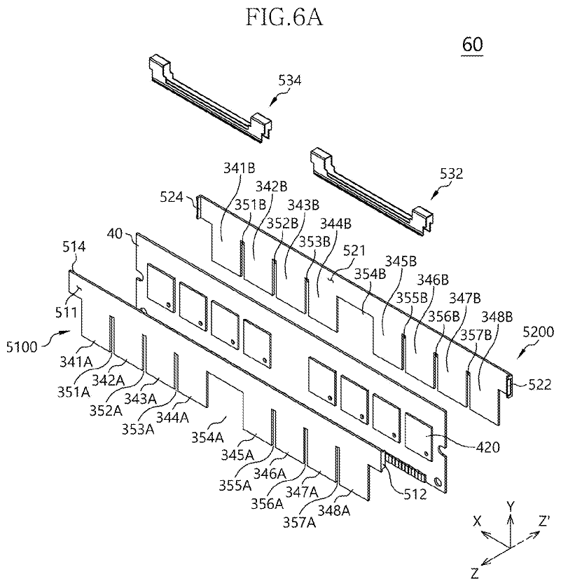

FIGS. 5A and 5B are views illustrating a heat spreader in accordance with example embodiments.

Referring to FIG. 5A, a heat spreader 50 of example embodiments may include a first heat spreading plate 510 and a second heat spreading plate 520.

The first and second heat spreading plates 510 and 520 may include a body 511 and 521, a plurality of cooling plates 341˜348 and at least one slot 351˜357. Each of the bodies 511 and 521 may have a plate shape extending in the lengthwise direction X of the memory module 40. The cooling plates 341˜348 may extend from the bodies 511 and 521 in the widthwise direction Y of the memory module 40 to cover the surfaces of the semiconductor chips 420. The slots 351˜357 may be formed between the cooling plates 341˜348.

In example embodiments, the first heat spreading plate 510 may include the body 511, a plurality of cooling plates 341A˜348A, at least one slot 351A-357A and combining tabs 512 and 514. The cooling plates 341A˜348A may extend from the body 511 in the widthwise direction Y of the memory module 40 to cover the surfaces of the semiconductor chips 420 on the memory module 40. The slots 351A-357A may be formed between the cooling plates 341A˜348A. The combining tabs 512 and 514 may be formed at both ends of the body 511 in the lengthwise direction X.

The second heat spreading plate 520 may include the body 521, a plurality of cooling plates 341B˜348B, at least one slot 351B-357B and combining grooves 522 and 524. The cooling plates 341B˜348B may extend from the body 521 in the widthwise direction Y of the memory module 40 to shield the surfaces of the semiconductor chips 420 on the memory module 40. The slots 351B-357B may be formed between the cooling plates 341B˜348B. The combining grooves 522 and 524 may be formed at both ends of the body 521 in the lengthwise direction X.

In example embodiments, the first heat spreading plate 510 may include the combining tabs 512 and 514 formed at the both ends of the first heat spreading plate 510 in the lengthwise direction X. The second heat spreading plate 520 may include the combining grooves 522 and 524 formed at the both ends of the second heat spreading plate 520 in the lengthwise direction X.

In example embodiments, the first heat spreading plate 510 may include the combining tab 512 at one end of the first heat spreading plate 510 in the lengthwise direction X and a combining groove at the other end of the first heat spreading plate 510 in the lengthwise direction. The second heat spreading plate 520 may include the combining groove 522 at one end of the second heat spreading plate 520 in the lengthwise direction X and a combining tip at the other end of the second heat spreading plate 520 in the lengthwise direction.

Referring to FIG. 5B, the first heat spreading plate 510 at the front of the memory module 40 and the second heat spreading plate 520 at the rear of the memory module 40 may be fixed to the memory module 40 by combining the combining tabs 512 and 514 with the combining grooves 522 and 524. The tabs 512 and 514 may be inserted into the combining grooves 522 and 524, respectively, to fasten the first head spreading plate 510 to the second heat spreading plate 520. In an embodiment, the tabs 512 and 514 are about the same size as the grooves 522 and 524 so that the grooves fasten to the tabs by a frictional interface between the tabs and the grooves.

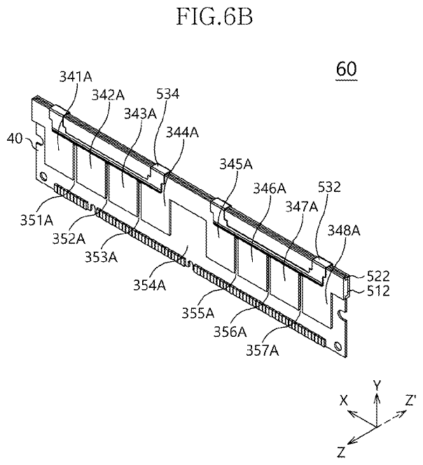

FIGS. 6A and 6B are views illustrating a heat spreader in accordance with example embodiments.

Referring to FIGS. 6A and 6B, a heat spreader 60 of example embodiments may include a first heat spreading plate 5100, a second heat spreading plate 5200 and at least one clip 532 and 534.

The clips 532 and 534 may be configured to fix and support the first heat spreading plate 5100 at the front of the memory module 40 and the second heat spreading plate 5200 at the rear of the memory module 40. The clips 532 and 534 have a window or open area along a middle part of the clips that straddles the spine of a memory module 40. The windows may allow air circulated by a fan to pass over surfaces of the heat spreading plates that would otherwise be covered by the clips.

The clips 532 and 534 may fix the first heat spreading plate 5100 to the front of the memory module 40 and the second heat spreading plate 4200 to the rear of the memory module 40. Thus, an embodiment of the heat spreader 60 may not include the combining tabs 512 and 514 of the first heat spreading plate 5100 and the combining grooves 522 and 524 of the second heat spreading plate 5200.

In example embodiments, lengths of the clips 532 and 534 extended from surfaces of the first and second heat spreading plates 5100 and 5200 may not shield the slots 351A-357A of the first heat spreading plate 5100 and the slots 351B-351B of the second heat spreading plate 5200.

As mentioned above, the heat spreader may include the cooling plates 341˜348 configured to cover the surfaces of the semiconductor chips 120, 220, 230 and 420 on the memory module 10, 20 and 40, and the slots 351˜357 formed between the cooling plates 341˜348.

Further, as shown in FIGS. 3 and 4, the heat spreader 30 may be integrally formed with the first and second heat spreading plates 310 and 320. As shown in FIGS. 5A and 5B, the heat spreader 50 may comprise two separable plates that are combined by a mechanical interface incorporated into the plates. Furthermore, as shown in FIG. 6, the heat spreader 60 may comprise two separable plates that are combined by one or more clip that compresses the plates to surfaces of a memory module. In an embodiment, the clip may be configured to apply a spring force that fixes plates to a memory module.

A heat spreader configured to fully cover the front and the rear of the memory module may not dissipate a heat absorbed from the memory module, which can deteriorate the power budget of the memory module.

In contrast, according to the heat spreader of example embodiments, heat from memory modules may be effectively dissipated through the slots between the cooling plates to decrease the power consumption of the memory module.

The above described embodiments of the present disclosure are intended to illustrate and not to limit the present disclosure. Various alternatives and equivalents are possible. The disclosure is not limited by the embodiments described herein. Nor is the disclosure limited to any specific type of semiconductor device. Another additions, subtractions, or modifications are obvious in view of the present disclosure and are intended to fall within the scope of the appended claims.

What is claimed is:

1. A heat spreader for a memory module including a plurality of semiconductor chips on at least one surface of a printed circuit board (PCB), the heat spreader comprising:
a first heat spreading plate disposed over a front surface of the memory module; and
a second heat spreading plate disposed over a rear surface of the memory module,
wherein at least one of the first and second heat spreading spreaders comprises:
a body that extends in a lengthwise direction of the memory module;
a plurality of cooling plates extending from the body in a widthwise direction of the memory module, each of the cooling plates covering a respective surface of one of the semiconductor chips; and
at least one slot between the cooling plates.

2. The heat spreader of claim 1, further comprising a connecting part that extends in the lengthwise direction and connects the first and second heat spreading plates with each other.

3. The heat spreader of claim 2, further comprising a module insertion groove disposed between the first and second heat spreading plates.

4. The heat spreader of claim 1, further comprising:
a combining tab provided on one end of at least one of the first and second heat spreading plates in the lengthwise direction; and
a combining groove provided on the other end of at least one of the first and second heat spreading plates in the lengthwise direction.

5. The heat spreader of claim 1, further comprising at least one clip configured to fix and support at least one of the first and second heat spreading plates.

6. A heat spreader for a memory module including a plurality of semiconductor chips on at least one surface of a printed circuit board (PCB), the heat spreader comprising:
a plurality of cooling plates configured to cover surfaces of the semiconductor chips; and
at least one slot between the cooling plates.

7. The heat spreader of claim 6, further comprising:
a first heat spreading plate configured to contact a front surface of the memory module; and
a second heat spreading plate configured to contact a rear surface of the memory module,
wherein the cooling plates and the slot are disposed in at least one of the first and second heat spreading plates.

8. The heat spreader of claim 7, wherein the first and second heat spreading plates are part of a single integral body.

9. The heat spreader of claim 7, wherein the first heat spreading plate and the second heat spreading plate are coupled by a tab that protrudes from at least one of the first and second heat spreading plates that interfaces with a groove disposed in at least one of the first and second heat spreading plates.

10. The heat spreader of claim 7, further comprising at least one clip configured to fix at least one of the first and second heat spreading plates to the memory module and support the at least one of the first and second heat spreading plates.
